(19) United States
(12) Patent Application Publication
(10) Pub. No.: US 2020/0363687 A1
(43) Pub. Date: Nov. 19, 2020

(54) CIRCUIT SUBSTRATE AND DISPLAY APPARATUS

(71) Applicant: SHARP KABUSHIKI KAISHA, Sakai City (JP)

(72) Inventors: TAKAYOSHI TANABE, Sakai City (JP); YUKIHIRO SUMIDA, Sakai City (JP)

(73) Assignee: SHARP KABUSHIKI KAISHA, Sakai City, Osaka (JP)

(21) Appl. No.: 16/872,867

(22) Filed: May 12, 2020

Related U.S. Application Data
(60) Provisional application No. 62/849,334, filed on May 17, 2019.

(51) Int. Cl. G02F 1/1362; G02F 1/1345; H05K 1/18

(52) U.S. Cl. CPC G02F 1/136204; G02F 1/13458; G09G 3/3648; H05K 1/189; G02F 1/13452

(57) ABSTRACT

A circuit substrate includes a substrate portion; a circuit portion that is provided on the substrate portion; a terminal portion that is provided on the substrate portion and connected to the circuit portion; and a dummy terminal portion that is disposed at a position closer to an edge than the terminal portion is on the substrate portion so as to be spaced from the terminal portion with an insulating space between the terminal portion and the dummy terminal portion.

### CROSS-REFERENCE TO RELATED APPLICATION

The present application claims priority from Provisional Application No. 62/849,334, the content to which is hereby incorporated by reference into this application.

### BACKGROUND OF THE INVENTION

### 1. Field of the Invention

The present invention relates to a circuit substrate and a display apparatus.

### 2. Description of the Related Art

As an example of a liquid crystal panel that has enhanced resistance against discharge due to invasion of static electricity from outside or due to contact, one described in PTL 1 described below is conventionally known. A liquid crystal panel described in Japanese Unexamined Patent Application Publication No. 2015-161753 includes an array substrate and a color filter substrate that has a transparent conductive film (CF transparent conductive film) formed on a surface thereof. The array substrate has ground wiring that is connected to the CF transparent conductive film and supplies a ground potential to the CF transparent conductive film, and CF ground checking wiring that is connected to the CF transparent conductive film separately from the ground wiring. The CF ground checking wiring extends along an outermost periphery portion on at least one side of the array substrate.

### SUMMARY OF THE INVENTION

In the liquid crystal panel described in Japanese Unexamined Patent Application Publication No. 2015-161753 described above, a discharge path constituted by the ground wiring, the CF ground checking wiring, and the like enables to release electro-static discharge (ESD) to the ground, thus making it possible to protect a driver IC or the like provided in the array substrate. The discharge path is provided in a picture-frame portion outside a display region in the array substrate. On the other hand, in recent years, picture-frame narrowing has tended to be required to narrow the picture-frame portion. With advance of the picture-frame narrowing, it becomes difficult to secure a space where the discharge path is installed, so that there is a trouble in a countermeasure against the ESD.

Moreover, in a structure of Japanese Unexamined Patent Application Publication No. 2015-161753 described above, the discharge path is formed only after the array substrate and the color filter substrate are brought into a bonded state. Thus, the discharge path is not formed in a state where the array substrate is alone and there is a problem that the driver IC or the like provided in the array substrate is difficult to be protected against the ESD.

An embodiment of the invention is completed on the basis of circumstances as described above and aims to achieve both a countermeasure against ESD and picture-frame narrowing.

(1) An embodiment of the invention is a circuit substrate including: a substrate portion; a circuit portion that is provided on the substrate portion; a terminal portion that is provided on the substrate portion and connected to the circuit portion; and a dummy terminal portion that is disposed at a position closer to an edge than the terminal portion is on the substrate portion so as to be spaced from the terminal portion with an insulating space between the terminal portion and the dummy terminal portion.

(2) Moreover, an embodiment of the invention is the circuit substrate in which thicknesses of the terminal portion and the dummy terminal portion are substantially identical with each other, in addition to the configuration of (1) described above.

(3) Moreover, an embodiment of the invention is the circuit substrate in which a plurality of terminal portions, each of which is the terminal portion that is provided on the substrate portion and connected to the circuit portion and a plurality of dummy terminal portions, each of which is the dummy terminal portion that is disposed at the position closer to the edge than the terminal portion is on the substrate portion so as to be spaced from the terminal portion with the insulating space between the terminal portion and the dummy terminal portion, are arranged each with an interval at positions with the insulating space between the plurality of terminal portions and the plurality of dummy terminal portions, and are equal in a width dimension and an array pitch, in addition to the configuration of (1) or (2) described above.

(4) Moreover, an embodiment of the invention is the circuit substrate in which the terminal portion and the dummy terminal portion are disposed so that a side edge of the terminal portion and a side edge of the dummy terminal portion along an arrangement direction are aligned so as to be in line with each other, in addition to the configuration of (3) described above.

(5) Moreover, an embodiment of the invention is the circuit substrate further including an insulating film that is provided on the substrate portion and disposed in the insulating space, in addition to the configuration of any one of (1) to (4) described above.

(6) Moreover, an embodiment of the invention is the circuit substrate in which thicknesses of the terminal portion, the dummy terminal portion, and the insulating film are substantially identical with each other, in addition to the configuration of (5) described above.

(7) Moreover, an embodiment of the invention is the circuit substrate further including an electronic component that is provided so as to be positioned between the terminal portion and the circuit portion on the substrate portion and electrically connected to the terminal portion and the circuit portion, in addition to the configuration of any one of (1) to (6) described above.

(8) Moreover, an embodiment of the invention is the circuit substrate in which the substrate portion is sectioned into a display region in which at least the circuit portion is disposed and an image is displayed and a non-display region which is disposed outside the display region and in which at least the terminal portion, the insulating space, and the dummy terminal portion are disposed, in addition to the configuration of any one of (1) to (7) described above.

(9) Moreover, an embodiment of the invention is the circuit substrate in which an end of the dummy terminal portion, which is closer to the edge of the substrate portion, is disposed so as to be flush with the edge of the substrate portion or so as to protrude from the edge of the substrate portion, in addition to the configuration of any one of (1) to (8) described above.

(10) Moreover, an embodiment of the invention is a display apparatus including the circuit substrate according to any one of (1) to (9) described above and a counter substrate that is bonded to the circuit substrate in an opposed manner.

According to an embodiment of the invention, it is possible to achieve both a countermeasure against ESD and picture-frame narrowing.

### BRIEF DESCRIPTION OF DRAWINGS

FIG. 1 is a plan view schematically illustrating a configuration of connection between a liquid crystal panel and a flexible substrate in a liquid crystal display apparatus according to Embodiment 1 of the invention.

FIG. 2 is a side view schematically illustrating the configuration of the connection between the liquid crystal panel and the flexible substrate.

FIG. 3 is a plan view schematically illustrating a configuration of wiring lines in a display region of an array substrate constituting the liquid crystal panel.

FIG. 4 is a sectional view taken along a line A-A in FIG. 3.

FIG. 5 is a plan view illustrating a configuration in a vicinity of a terminal portion and a dummy terminal portion in the array substrate.

FIG. 6 is a plan view illustrating a configuration in a vicinity of a terminal portion in the flexible substrate.

FIG. 7 is a sectional view illustrating a configuration in a state where the flexible substrate is mounted on the array substrate.

FIG. 8 is a sectional view illustrating a configuration of the terminal portion and the dummy terminal portion in the array substrate.

FIG. 9 is a plan view when the flexible substrate is mounted on the terminal portion of the array substrate without positional deviation.

FIG. 10 is a plan view when the flexible substrate is mounted on the terminal portion of the array substrate with positional deviation in a θ direction.

FIG. 11 is a sectional view illustrating a configuration in a vicinity of a terminal portion and a dummy terminal portion according to Embodiment 2 of the invention.

FIG. 12 is a plan view illustrating a configuration in the vicinity of the terminal portion and the dummy terminal portion.

FIG. 13 is a sectional view illustrating a configuration in a state where a flexible substrate is mounted on an array substrate.

FIG. 14 is a plan view schematically illustrating a configuration of connection between a liquid crystal panel, a driver IC, and a flexible substrate in a liquid crystal display apparatus according to Embodiment 3 of the invention.

FIG. 15 is a sectional view illustrating a configuration in a state where the flexible substrate is mounted on the array substrate.

FIG. 16 is a sectional view illustrating a configuration of a terminal portion and a dummy terminal portion in the array substrate.

FIG. 17 is a sectional view illustrating a configuration in a vicinity of a terminal portion and a dummy terminal portion according to Embodiment 4 of the invention.

FIG. 18 is a plan view illustrating a configuration in a vicinity of the terminal portion and the dummy terminal portion.

FIG. 19 is a plan view illustrating a configuration in a vicinity of a terminal portion and a dummy terminal portion according to Embodiment 5 of the invention.

FIG. 20 is a sectional view illustrating a configuration of the terminal portion and the dummy terminal portion in the array substrate.

### DETAILED DESCRIPTION OF THE INVENTION

### Embodiment 1

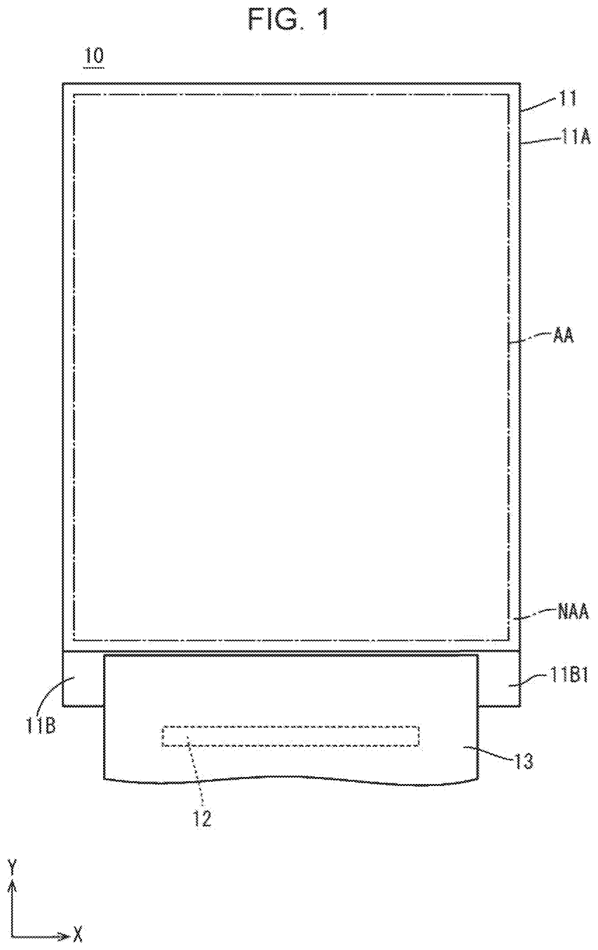

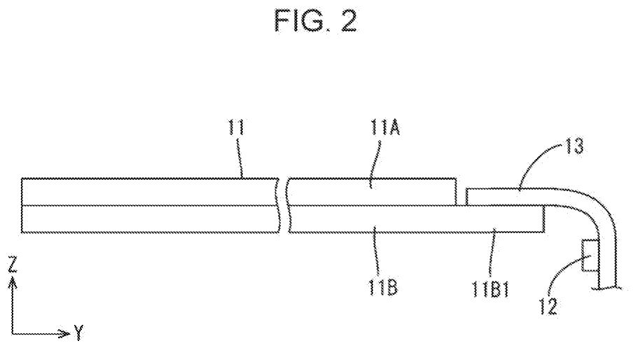

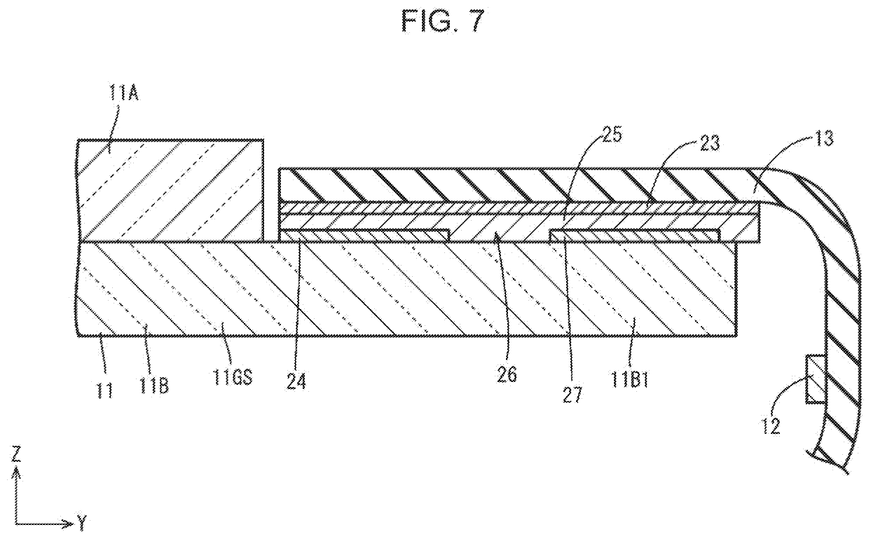

Embodiment 1 of the invention will be described with reference to FIGS. 1 to 10. In the present embodiment, a liquid crystal panel 11 provided in a liquid crystal display apparatus 10 is exemplified. Note that, an X-axis, a Y-axis, and a Z-axis are illustrated at a part of each of drawings and X-axis, Y-axis, and Z-axis directions represent directions common in the drawings. An upper side and a lower side in FIGS. 2, 7, and the like are respectively defined as a front side and a back side.

As illustrated in FIG. 1, the liquid crystal display apparatus 10 includes at least the liquid crystal panel 11 capable of displaying an image, a flexible substrate (external connection component) 13 that electrically connects the liquid crystal panel 11 and an external control circuit substrate, a driver IC (panel drive portion, drive circuit) 12 that is mounted on the flexible substrate 13 and drives the liquid crystal panel 11, a control circuit substrate (external signal supply source) that supplies various types of input signals from outside to the driver IC 12, and a backlight device serving as an external light source that is disposed on a back side of the liquid crystal panel 11 and emits light for display on the liquid crystal panel 11.

As illustrated in FIG. 1, the liquid crystal panel 11 is longitudinally elongated quadrangular (rectangular) as a whole and has a plate surface sectioned into a display region (active area) AA in which an image is able to be displayed and which is disposed on a central side, and a non-display region (non-active area) NAA which is disposed on an outer peripheral side in a form of surrounding the display region AA and has a rim shape (frame shape) in plan view. A short-side direction in the liquid crystal panel 11 coincides with the X-axis direction in each of the drawings, a long-side direction thereof coincides with the Y-axis direction in each of the drawings, and further, a plate thickness direction coincides with the Z-axis direction. Note that, in FIG. 1, a one-dot chain line represents an outer shape of the display region AA, and a region outer than the one-dot chain line is the non-display region NAA.

As illustrated in FIG. 1, a CF substrate 11A that forms the liquid crystal panel 11 has a long-side dimension shorter than a long-side dimension of an array substrate 11B and is bonded to the array substrate 11B so that one of short-side parts of the CF substrate 11A and one of short-side parts of the array substrate 11B are matched. Thus, the other short-side part of the array substrate 11B in the long-side direction serves as a CF substrate non-overlapping portion (first side portion) 11B1 that is projected from the CF substrate 11A to a side and is not overlapped with the CF substrate 11A. The CF substrate non-overlapping portion 11B1 belongs to the non-display region NAA. The flexible substrate 13 is mounted on the CF substrate non-overlapping portion 11B1. A configuration related to a region where the flexible substrate 13 is mounted on the CF substrate non-overlapping portion 11B1 will be described later again.

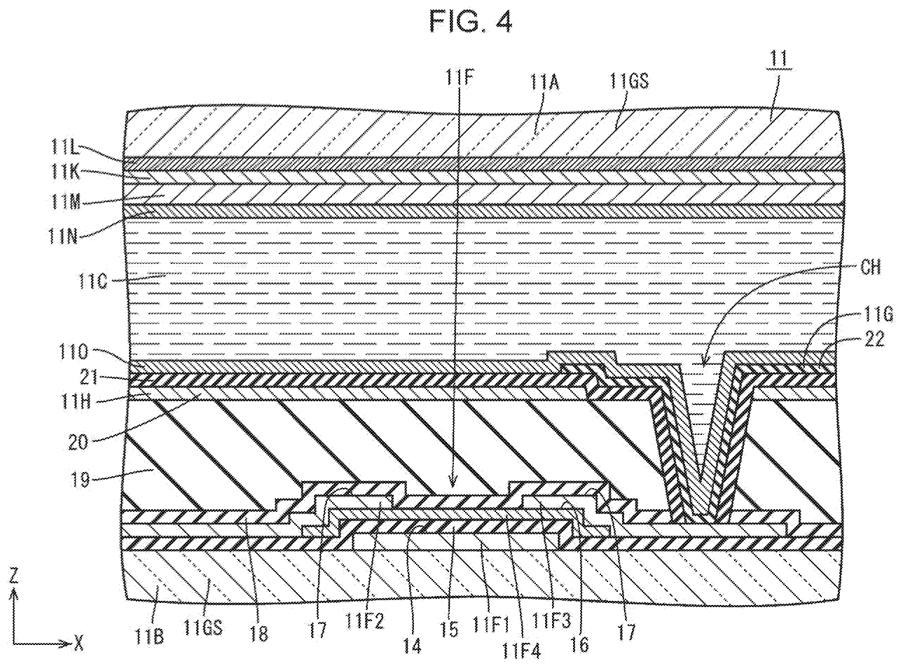

As illustrated in FIGS. 2 and 4, the liquid crystal panel 11 has at least a pair of substrates 11A and 11B and a liquid crystal layer (inner space) 11C interposed between both of the substrates 11A and 11B and including liquid crystal molecules which are a substance whose optical characteristics change when an electric field is applied. Out of the pair of substrates 11A and 11B, a front side (face side) is the CF substrate (counter substrate) 11A, and a back side (rear side) is the array substrate (circuit substrate, TFT substrate) 11B. Each of the CF substrate 11A and the array substrate 11B is formed so that various types of films are layered on an inner surface side of a glass substrate (substrate portion) 11GS made of glass.

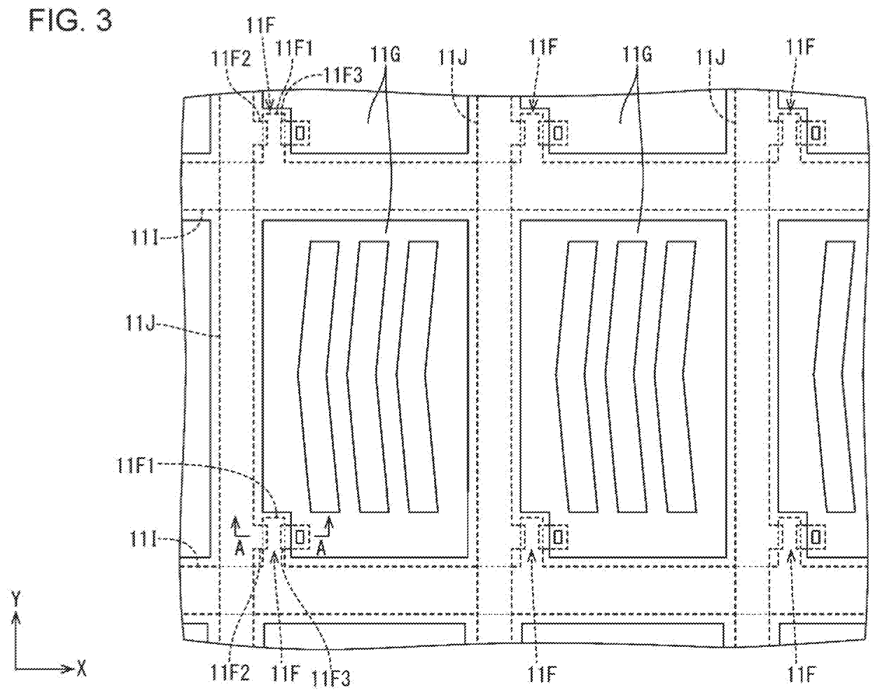

As illustrated in FIG. 3, in the display region AA on an inner surface side (on the liquid crystal layer 11C side, on a side facing the CF substrate 11A) of the array substrate 11B, numerous thin film transistors (TFTs) 11F, which are switching elements, and numerous pixel electrodes 11G are arrayed in a matrix (in rows and columns), and gate lines (scanning lines) 11I and source lines (circuit portions, data lines, signal lines) 11J that are formed in a grid pattern are arranged so as to surround the TFTs 11F and the pixel electrodes 11G. Each of the gate lines 11I and each of the source lines 11J are respectively connected to a gate electrode 11F1 and a source electrode 11F2 of corresponding one of the TFTs 11F, and each of the pixel electrodes 11G is connected to a drain electrode 11F3 of corresponding one of the TFTs 11F. The TFTs 11F are driven on the basis of various types of signals supplied to the gate lines 11I and the source lines 11J, and in accordance with the driving, supply of an electric potential to the pixel electrodes 11G is controlled. The pixel electrodes 11G are each disposed in a quadrangular region surrounded by the gate lines 11I and the source lines 11J. Moreover, in the display region AA on the inner surface side of the array substrate 11B, a common electrode 11H formed of a solid pattern is formed on an upper layer side relative to the pixel electrodes 11G so as to overlap with the pixel electrodes 11G. When potential difference is generated between the pixel electrodes 11G and the common electrode 11H that overlap with each other, a fringe electric field (oblique electric field) including a component in a direction normal to a plate surface of the array substrate 11B is applied to the liquid crystal layer 11C in addition to a component in a direction along the plate surface of the array substrate 11B. That is, an operation mode of the liquid crystal panel 11 according to the present embodiment is set as a fringe field switching (FFS) mode. Note that, in the present embodiment, in the drawings, it is assumed that an extending direction of the gate lines 11I coincides with the X-axis direction and an extending direction of the source lines 11J coincides with the Y-axis direction.

On the other hand, as illustrated in FIG. 3, in the display region AA on the inner surface side of the CF substrate 11A, numerous color filters 11K are provided side by side in a matrix at positions facing the respective pixel electrodes 11G on the array substrate 11B side. The color filters 11K have colored films in three colors of R (red), G (green), and B (blue) repeatedly arrayed in predetermined order. Between the color filters 11K, a light blocking film (black matrix) 11L having a grid pattern is formed to prevent color mixture. The light blocking film 11L is arranged so as to be overlapped with the gate lines 11I and the source lines 11J described above in plan view. On surfaces of the color filters 11K and the light blocking film 11L, an overcoat film 11M is provided. Further, on a surface of the overcoat film 11M, a not-illustrated photo spacer is provided. Note that, in the liquid crystal panel 11, one display pixel that is a display unit is constituted by the colored films in three colors of R, G, and B of the color filters 11K and three pixel electrodes 11G facing the colored films. The display pixel includes a red pixel having a color filter 11K in R, a green pixel having a color filter 11K in G, and a blue pixel having a color filter 11K in B. Display pixels in the respective colors are repeatedly disposed on the plate surface of the liquid crystal panel 11 along a row direction (the X-axis direction) so as to form a group of display pixels. Numerous groups of display pixels are disposed side by side along a column direction (the Y-axis direction). In both of the substrates 11A and 11B, as layers that are innermost (near the liquid crystal layer 11C) and in contact with the liquid crystal layer 11C, alignment films 11N and 11O for aligning the liquid crystal molecules included in the liquid crystal layer 11C are respectively formed.

Next, various types of films formed in layers on the inner surface side of the array substrate 11B will be described. As illustrated in FIG. 4, in order from a lower layer side (a glass substrate 11GS side, a side far from the liquid crystal layer 11C), a first metal film (gate metal film) 14, a gate insulating film 15, a semiconductor film 16, a second metal film (source metal film) 17, a first interlayer insulating film 18, a planarizing film (first insulating film, lower-layer side insulating film) 19, a first transparent electrode film 20, a second interlayer insulating film (second insulating film, upper-layer side insulating film) 21, a second transparent electrode film 22, and the alignment film 11O are formed in layers.

The first metal film 14 is a multilayer film in which different types of metal materials are layered or a single-layer film composed of one type of a metal material, and forms the gate lines 11I, gate electrodes 11F1 of the TFTs 11F, and the like as illustrated in FIG. 4. The gate insulating film 15 is composed of an inorganic insulating material (inorganic resin material). The semiconductor film 16 is formed of a thin film whose material is, for example, an oxide semiconductor and constitutes a channel portion 11F4 and the like connected to the source electrodes 11F2 and the drain electrodes 11F3 in the TFTs 11F. Similarly to the first metal film 14, the second metal film 17 is a multilayer film or a single-layer film and constitutes the source lines 11J, the source electrodes 11F2 and the drain electrodes 11F3 of the TFTs 11F, and the like. The first interlayer insulating film 18 is composed of an inorganic insulating material. The planarizing film 19 is composed of an organic insulating material (organic resin material), for example, such as PMMA (acrylic resin) and has a film thickness that is greater than that of other insulating films 15, 18, and 21 composed of an inorganic resin material and that is about several μm. The planarizing film 19 planarizes the surface of the array substrate 11B. The first transparent electrode film 20 is composed of a transparent electrode material, for example, such as ITO and constitutes the common electrode 11H. The second interlayer insulating film 21 is composed of an inorganic insulating material, for example, such as SiNx. The second transparent electrode film 22 is composed of a transparent electrode material and constitutes the pixel electrodes 11G. At the first interlayer insulating film 18, the planarizing film 19, and the second interlayer insulating film 21, a contact hole CH by which the pixel electrode 11G formed of the second transparent electrode film 22 is connected to the drain electrode 11F3 formed of the second metal film 17 is formed to be opened. Excluding the contact hole CH, the first interlayer insulating film 18, the planarizing film 19, and the second interlayer insulating film 21 are formed in a solid state at least over the entire display region AA. The alignment film 11O is layered on the upper layer side of the second transparent electrode film 22 and the second interlayer insulating film 21 so as to be directly opposed to the liquid crystal layer 11C.

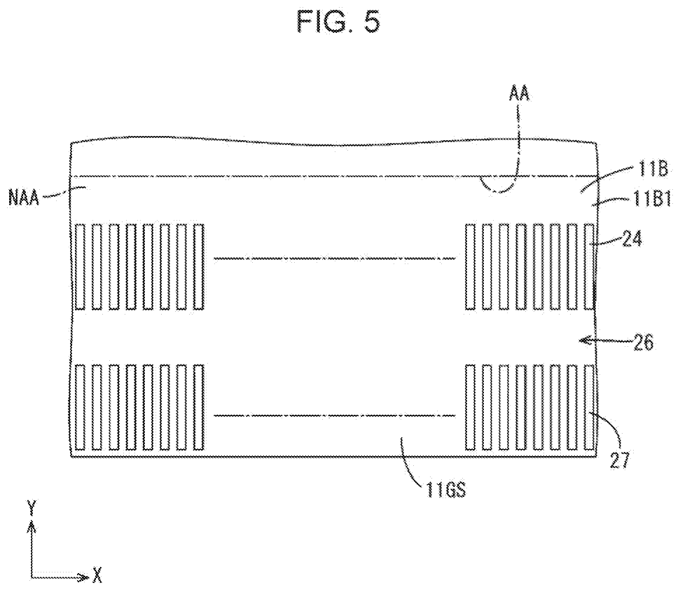

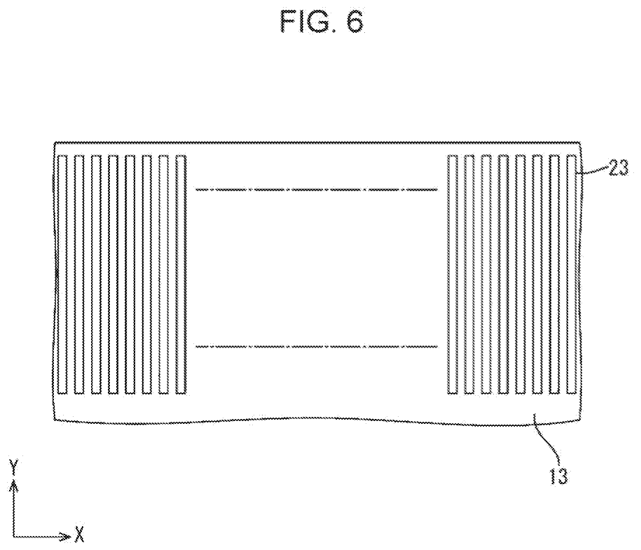

The configuration related to the region where the flexible substrate 13 is mounted on the CF substrate non-overlapping portion 11B1 will be described. In the region where the flexible substrate 13 is mounted on the CF substrate non-overlapping portion 11B1, as illustrated in FIGS. 5 and 7, terminal portions 24 electrically connected to respective terminal portions 23 (refer to FIG. 6), which are provided in the flexible substrate 13, via an anisotropic conductive film (ACF) 25 are provided. The terminal portions 24 are mainly constituted by the first metal film 14 and the second metal film 17 that are provided in the array substrate 11B and numerous terminal portions 24 are disposed side by side each with an interval along the X-axis direction in the region where the flexible substrate 13 is mounted. The terminal portions 24 are connected to the source lines 11J and the like disposed in the display region AA via connection lines, and when a signal transferred by the flexible substrate 13 is input to the terminal portions 24, the signal is supplied to the source lines 11J and the like via the connection lines.

The flexible substrate 13 is obtained in such a manner that wiring patterns formed of a metal film (for example, copper film) and the terminal portions 23 are appropriately formed as illustrated in FIG. 6 on a film composed of an insulating material having a light transmissive property, such as polyimide. Similarly to the terminal portions 24 provided in the array substrate 11B, numerous terminal portions 23 provided in the flexible substrate 13 are disposed side by side each with an interval along the X-axis direction, and a width dimension and an array pitch thereof are almost the same as those of the terminal portions 24. As illustrated in FIG. 1, on the flexible substrate 13, the driver IC 12 is chip on film (COF) mounted. This makes it possible to achieve picture-frame narrowing of the liquid crystal panel 11 as compared to a case where it is assumed that the drive IC 12 is chip on glass (COG) mounted on the array substrate 11B. The flexible substrate 13 is different from a rigid substrate in terms of having flexibility and being elastically bendable. By using such characteristics, in the flexible substrate 13, a part that extends outside from a part connected to the array substrate 11B is bent to be directed to the back side of the array substrate 11B as illustrated in FIG. 7.

The anisotropic conductive film 25 is obtained by dispersing and compounding fine conductive particles in thermosetting resin such as epoxy and processing the resultant into a film shape. As illustrated in FIG. 7, by performing heating while applying pressure along the Z-axis direction in a state where the anisotropic conductive film 25 is interposed between the terminal portions 24 of the array substrate 11B and the terminal portions 23 of the flexible substrate 13, the terminal portions 23 and 24 that are arrayed in the Z-axis direction that is a direction in which the pressure is applied are electrically connected selectively via the conductive particles.

Meanwhile, in a process of manufacturing the array substrate 11B configured as described above, the glass substrate 11GS may be exposed to a surge caused by ESD. Such a surge tends to be easily input to a vicinity of an edge of the glass substrate 11GS. The terminal portions 24 are arranged in the vicinity of the edge of the glass substrate 11GS, and when it is assumed that the surge is input to a terminal portion 24, the surge is input to a corresponding one of the source lines 11J in the display region AA via corresponding one of the connection lines so that the source line 11J may be disconnected or the TFT 11F connected to the source line 11J may undergo electrostatic breakdown.

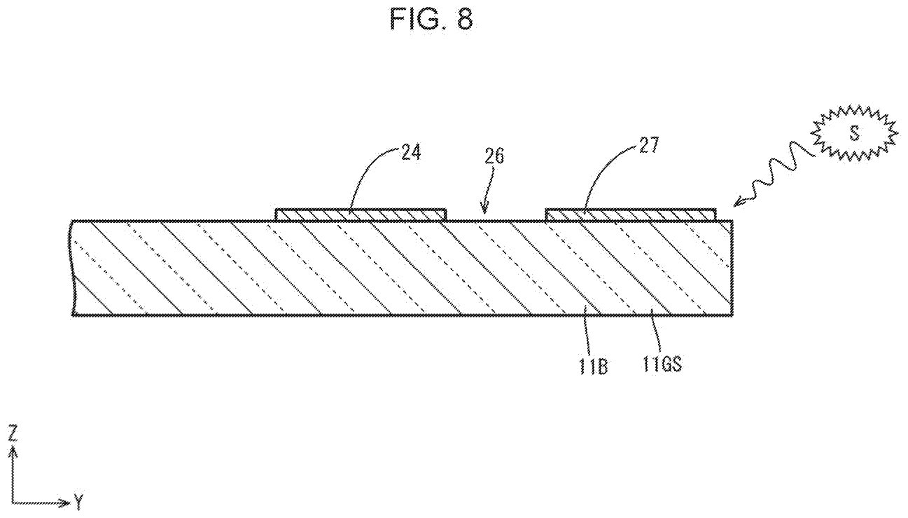

Thus, in the array substrate 11B according to the present embodiment, at a position closer to the edge than the terminal portion 24 is on the substrate portion 11GS, a dummy terminal portion 27 that is arranged so as to be spaced from the terminal portion 24 with an insulating space 26 therebetween is provided as illustrated in FIGS. 5 and 8. Specifically, the dummy terminal portion 27 is arranged on a side opposite to the display region AA side so as to be spaced from the terminal portion 24 with an interval of the insulating space 26 in the Y-axis direction. That is, in the region where the flexible substrate 13 is mounted on the CF substrate non-overlapping portion 11B1 of the array substrate 11B, the terminal portion 24, the insulating space 26, and the dummy terminal portion 27 are arranged in this order from the display region AA side to the edge side of the glass substrate 11GS. A direction in which the terminal portion 24, the insulating space 26, and the dummy terminal portion 27 are arranged coincides with the Y-axis direction in each of the drawings. Moreover, the dummy terminal portion 27 is arranged at a position with a fixed interval (margin) from the edge of the glass substrate 11GS in the Y-axis direction. According to such a configuration, in a case where the glass substrate 11GS is exposed to a surge caused by ESD in the process of manufacturing the array substrate 11B, the surge is easily input to the dummy terminal portion 27 disposed on the edge side of the glass substrate 11GS so as to be spaced from the terminal portion 24 with the insulating space 26 therebetween. Since the terminal portion 24 is separated from the dummy terminal portion 27 by the insulating space 26, reaching of the surge, which is input to the dummy terminal portion 27, to the terminal portion 24 is avoided. Accordingly, since the surge is difficult to be input to the terminal portion 24, the source line 11J connected to the terminal portion 24 or the TFT 11F is able to be protected against the surge caused by the ESD. As a result, since disconnection of the source line 11J is difficult to be generated and electrostatic breakdown is difficult to occur in the TFT 11F, display failure is difficult to be caused in the display region and high display quality is obtained.

Additionally, as compared to a conventional case where a discharge path formed of ground wiring, CF ground checking wiring, and the like is installed as a countermeasure against the ESD, a space of the insulating space 26 and the dummy terminal portion 27 occupied in the glass substrate 11GS is generally narrow in the present embodiment. This is suitable for achieving picture-frame narrowing of the glass substrate 11GS. Moreover, as compared to a conventional case where a driver IC or the like is difficult to be protected against the surge caused by the ESD in a process of manufacturing an array substrate because the discharge path is formed only after the array substrate and a color filter substrate are brought into a bonded state, the present embodiment enables to protect the source line 11J or the like against the surge caused by the ESD even by the array substrate 11B alone (including the manufacturing process).

As illustrated in FIG. 5, numerous dummy terminal portions 27 are disposed side by side with an interval along the X-axis direction in the region where the flexible substrate 13 is mounted, and a width dimension and an array pitch thereof are almost the same as those of the terminal portions 24. Thereby, the plurality of terminal portions 24 and the plurality of dummy terminal portions 27 are equal in an array pattern. As a result, when the terminal portions 24 and the dummy terminal portions 27 are press-bonded to the terminal portions 23 of the flexible substrate 13 via the anisotropic conductive film 25, the terminal portions 24 and the dummy terminal portions 27 are equal in a press-bonding state of the anisotropic conductive film 25, so that bonding intensity and connection reliability after pressure bonding become excellent.

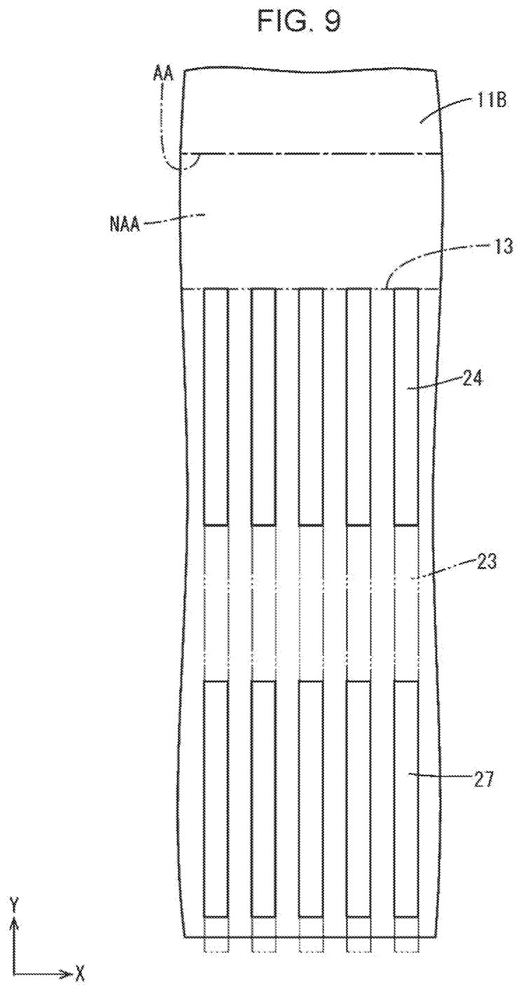

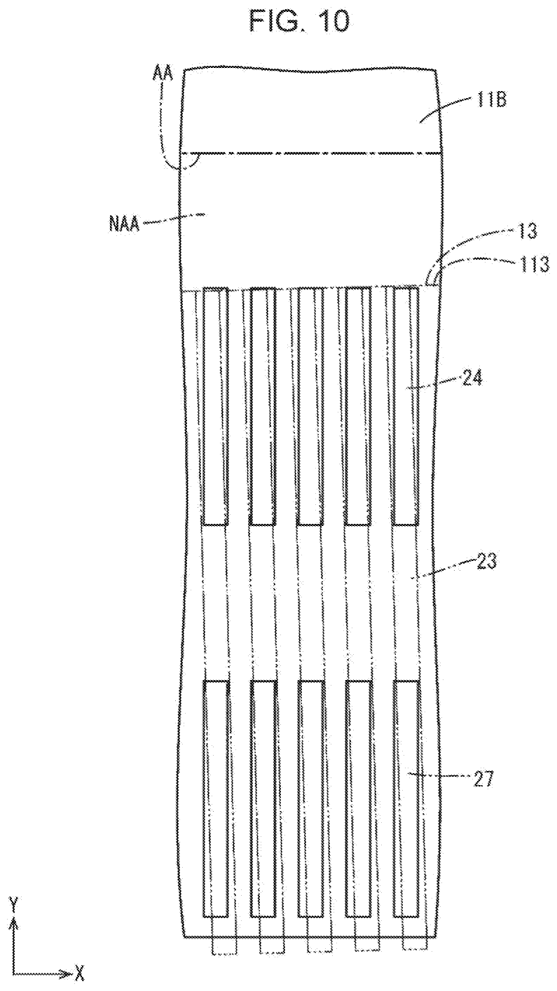

Further, as illustrated in FIG. 5, each of the dummy terminal portions 27 is disposed so that a side edge thereof and a side edge of each of the terminal portions 24 along the Y-axis direction (arrangement direction) are aligned so as to be in line with each other. On the other hand, the width dimension and the array pitch of the terminal portions 23 of the flexible substrate 13 are almost the same as those of the terminal portions 24 and the dummy terminal portions 27 as described above. Thus, when the flexible substrate 13 is mounted on the array substrate 11B at an appropriate position in the X-axis direction or a θ direction that is a rotational direction about the Z-axis on an XY plane, a positional relationship in which a side edge of a terminal portion 23 of the flexible substrate 13 almost matches the side edge of the terminal portion 24 and the side edge of the dummy terminal portion 27 as illustrated in FIG. 9 is obtained. Note that, a configuration related to the flexible substrate 13 is illustrated by a two-dot chain line in FIG. 9. In this case, the terminal portion 24 and the dummy terminal portion 27 are hardly recognized visually through a film of the flexible substrate 13, which has the light transmissive property. On the other hand, in a case where the flexible substrate 13 is mounted on the array substrate 11B in a state of being deviated in the X-axis direction or the aforementioned θ direction, a positional relationship in which a part of or entire side edge of the terminal portion 23 of the flexible substrate 13 does not match the side edge of the terminal portion 24 or the side edge of the dummy terminal portion 27 as illustrated in FIG. 10 is obtained. Note that, the configuration related to the flexible substrate 13 is illustrated by a two-dot chain line in FIG. 10. In this case, the terminal portion 24 and the dummy terminal portion 27 are recognized visually through the film of the flexible substrate 13, which has the light transmissive property. In this manner, on the basis of whether or not the terminal portion 24 and the dummy terminal portion 27 are recognized visually through the flexible substrate 13, it is possible to determine whether or not the flexible substrate 13 is appropriately mounted. This makes it possible to easily detect positional deviation of the flexible substrate 13 by observation with a microscope or image recognition.

Similarly to the terminal portion 24, the dummy terminal portion 27 is mainly constituted by the first metal film 14 and the second metal film 17 that are provided in the array substrate 11B. As illustrated in FIG. 7, a thickness of the dummy terminal portion 27 is almost the same as a thickness of the terminal portion 24. On the other hand, a dimension of the terminal portion 23 of the flexible substrate 13 in the Y-axis direction is the same as or larger than a size corresponding to a sum of dimensions of the terminal portion 24, the insulating space 26, and the dummy terminal portion 27 in the Y-axis direction. Thus, when the flexible substrate 13 is mounted on the array substrate 11B, thermal pressure bonding is performed in a state where the anisotropic conductive film 25 is interposed between the terminal portion 24 and the dummy terminal portion 27, and the terminal portion 23 of the flexible substrate 13. At this time, since the terminal portion 24 and the dummy terminal portion 27 are equal in the thickness, an equal pressure is applied to a part interposed between the terminal portion 24 and the terminal portion 23 of the flexible substrate 13 and a part interposed between the dummy terminal portion 27 and the terminal portion 23 of the flexible substrate 13 in the anisotropic conductive film 25. Thus, supposedly, as compared to a case where there is a difference between the thicknesses of the terminal portion 24 and the dummy terminal portion, improvement of bonding intensity is achieved and connection reliability between the terminal portion 24 and the terminal portion 23 of the flexible substrate 13 becomes high. Further, a film configuration of the dummy terminal portion 27 is more preferably the same as a film configuration of the terminal portion 24. This makes it possible to form the terminal portion 24 and the dummy terminal portion 27 with the same process in a case of manufacturing the array substrate 11B.

Moreover, as illustrated in FIG. 7, the dimension of each of the terminal portion 23 of the flexible substrate 13 and the anisotropic conductive film 25 in the Y-axis direction is preferably larger than a size corresponding to a sum of the dimensions of the terminal portion 24, the insulating space 26, and the dummy terminal portion 27 in the Y-axis direction. Thereby, in a case where the flexible substrate 13 is mounted on the array substrate 11B, even when the flexible substrate 13 and the anisotropic conductive film 25 are arranged so as to be slightly deviated from the array substrate 11B in the Y-axis direction, the anisotropic conductive film 25 is more reliably interposed between the terminal portion 24 and the dummy terminal portion 27, and the terminal portion 23 of the flexible substrate 13. As a result, a variation is difficult to be generated in pressure applied to the anisotropic conductive film 25 interposed between the terminal portion 24 and the dummy terminal portion 27, and the terminal portion 23 of the flexible substrate 13, so that much higher connection reliability is obtained.

As described above, the array substrate (circuit substrate) 11B according to the present embodiment includes: the glass substrate (substrate portion) 11GS; the source line (circuit portion) 11J that is provided in the glass substrate 11GS; the terminal portion 24 that is provided in the glass substrate 11GS and connected to the source line 11J; and the dummy terminal portion 27 that is arranged at a position closer to the edge than the terminal portion 24 is on the substrate portion 11GS so as to be spaced from the terminal portion 24 with the insulating space 26 therebetween. According to such a configuration, a signal is able to be supplied from outside to the source line 11J via the terminal portion 24. Meanwhile, in the process of manufacturing the array substrate 11B, the glass substrate 11GS may be exposed to the surge caused by the ESD depending on a manufacturing environment. Such a surge tends to be easily input particularly to a vicinity of the edge of the glass substrate 11GS. In this regard, since the dummy terminal portion 27 is arranged on the edge side of the glass substrate 11GS so as to be spaced from the terminal portion 24 with the insulating space 26 therebetween, even when the glass substrate 11GS is exposed to the surge caused by the ESD, the surge is easily input to the dummy terminal portion 27 as compared to the terminal portion 24. Since the terminal portion 24 is separated from the dummy terminal portion 27 by the insulating space 26, reaching of the surge, which is input to the dummy terminal portion 27, to the terminal portion 24 is avoided. Accordingly, the source line (circuit portion) 11J connected to the terminal portion 24 is able to be protected against the surge caused by the ESD.

Moreover, a function of protection against the ESD as described above is exerted regardless of a positional relationship between the edge of the glass substrate 11GS and an end of the dummy terminal portion 27 on the edge side of the glass substrate 11GS, so that a tolerance for the aforementioned positional relationship is able to be increased. Accordingly, in a case where the array substrate 11B is manufactured, for example, through a process of dividing a large-sized mother glass substrate and extracting the glass substrate 11GS, accuracy of division is able to be less stringent.

Additionally, as compared to a conventional case where a discharge path formed of ground wiring, CF ground checking wiring, and the like is installed as a countermeasure against the ESD, a space of the insulating space 26 and the dummy terminal portion 27 occupied in the glass substrate 11GS is generally narrow. This is suitable for achieving picture-frame narrowing of the glass substrate 11GS. Moreover, as compared to a conventional case where a discharge path is formed only after an array substrate and a color filter substrate are brought into a bonded state, the source line 11J is able to be protected against the surge caused by the ESD even by the present circuit substrate 11B alone (including the manufacturing process).

Moreover, the array substrate 11B according to the present embodiment is characterized in that the thicknesses of the terminal portion 24 and the dummy terminal portion 27 are substantially the same. Thereby, the terminal portion 24 and the dummy terminal portion 27 are equal in a height from the plate surface of the glass substrate 11GS. Meanwhile, when the terminal portion 23 of the flexible substrate (another circuit substrate) 13 is physically and electrically connected to the terminal portion 24, pressure bonding is performed by interposing the anisotropic conductive film 25 between both of the terminal portions 24 and 23 in some cases. In such a case, when a difference between the thicknesses of the terminal portion 24 and the dummy terminal portion 27 is great, pressure applied to the anisotropic conductive film 25 during the pressure bonding becomes easily nonuniform, so that bonding intensity and connection reliability may not be sufficiently obtained. In this regard, when the thicknesses of the terminal portion 24 and the dummy terminal portion 27 are substantially the same, the pressure applied to the anisotropic conductive film 25 during the pressure bonding is made uniform. This makes it possible to improve bonding intensity and connection reliability.

Moreover, in the array substrate 11B according to the present embodiment, a plurality of terminal portions 24 and a plurality of dummy terminal portions 27 are disposed each with an interval at positions with the insulating space 26 between the plurality of terminal portions 24 and the plurality of dummy terminal portions 27 and are equal in the width dimension and the array pitch. Thereby, the plurality of terminal portions 24 and the plurality of dummy terminal portions 27 are equal in the array pattern. Thus, when the terminal portion 24 is press-bonded to the terminal portion 23 of the flexible substrate 13 via the anisotropic conductive film 25, the terminal portion 24 and the dummy terminal portion 27 are equal in a press-bonding state of the anisotropic conductive film 25. As a result, bonding intensity and connection reliability after pressure bonding become excellent.

Moreover, in the array substrate 11B according to the present embodiment, the terminal portion 24 and the dummy terminal portion 27 are disposed so that the side edge of the terminal portion 24 and the side edge of the dummy terminal portion 27 along the arrangement direction are aligned so as to be in line with each other. On the other hand, as described above, the array substrate 11B and the flexible substrate 13 are connected by using the anisotropic conductive film 25 in some cases. In such a case, when the flexible substrate 13 has the light transmissive property, the terminal portion 24 and the dummy terminal portion 27 are able to be recognized visually through the flexible substrate 13 even after the flexible substrate 13 is connected. Here, since the terminal portion 24 and the dummy terminal portion 27 are disposed so that the side edge of the terminal portion 24 and the side edge of the dummy terminal portion 27 along the arrangement direction are aligned so as to be in line with each other, when the flexible substrate 13 is mounted on the array substrate 11B in a state of being deviated in a direction (the X-axis direction or the aforementioned θ direction) crossing the arrangement direction, the terminal portion 24 and the dummy terminal portion 27 are seen differently through the flexible substrate 13. This makes it possible to easily detect the positional deviation of the flexible substrate 13 by observation with a microscope or image recognition.

Moreover, the array substrate 11B according to the present embodiment is sectioned into the display region AA in which at least the source line 11J is disposed and an image is displayed and the non-display region NAA which is disposed outside the display region AA and in which at least the terminal portion 24, the insulating space 26, and the dummy terminal portion 27 are disposed. As a result, when a signal input to the terminal portion 24 disposed in the non-display region NAA of the substrate portion 11GS is supplied to the source line 11J disposed in the display region AA, an image is displayed in the display region AA. Since resistance against the ESD of the source line 11J is improved by the dummy terminal portion 27 disposed in the non-display region NAA, an image display function of the source line 11J is more reliably exerted. Thereby, display failure caused by the ESD is difficult to be caused. Additionally, a space of the insulating space 26 and the dummy terminal portion 27 occupied in the glass substrate 11GS is small, thus making it possible to narrow the non-display region NAA. As a result, excellent appearance and excellent design are obtained.

Moreover, the liquid crystal panel 11 according to the present embodiment includes the array substrate 11B and the CF substrate (counter substrate) 11A bonded to the array substrate 11B in an opposed manner. According to the liquid crystal panel 11 configured as described above, resistance against the ESD of the source line 11J provided in the array substrate 11B is improved, so that display failure caused by the ESD is difficult to be caused. Additionally, a function of protection against the ESD by the dummy terminal portion 27 and the insulating space 26 is exerted also at a stage before the CF substrate 11A is bonded to the array substrate 11B, that is, in a state of the array substrate 11B alone. Accordingly, as compared to a conventional case where a discharge path is formed only after an array substrate and a color filter substrate are brought into a bonded state, the source line 11J is able to be protected against the surge caused by the ESD with high reliability. Additionally, a space of the insulating space 26 and the dummy terminal portion 27 occupied in the glass substrate 11GS of the array substrate 11B is small, thus making it possible to achieve picture-frame narrowing of the liquid crystal panel 11. As a result, excellent appearance and excellent design are obtained.

### Embodiment 2

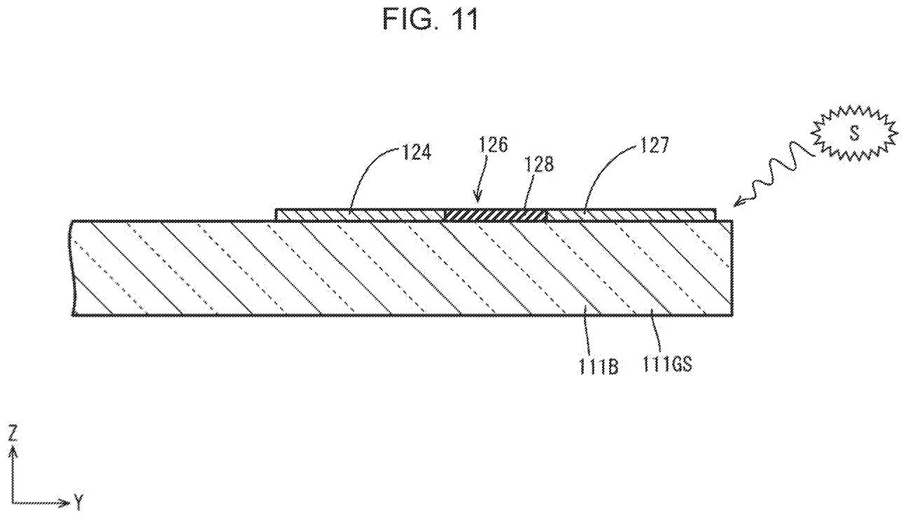

Embodiment 2 of the invention will be described with reference to FIGS. 11 to 13. In Embodiment 2, in addition to the configuration of Embodiment 1, an array substrate 111B includes an insulating film 128 disposed in an insulating space 126. Note that, one having a similar configuration to that of Embodiment 1 described above will be given the same reference sign and redundant description for a structure, an action, and an effect thereof will be omitted.

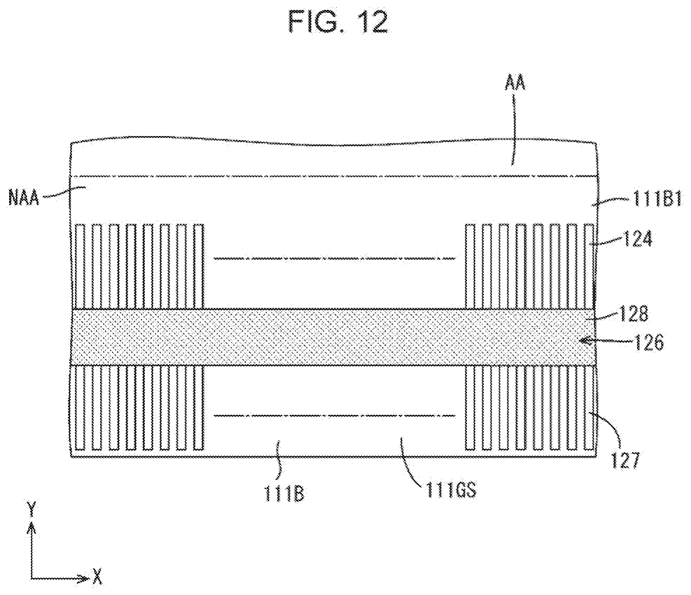

In the array substrate 111B according to the present embodiment, the insulating space 126 disposed between a terminal portion 124 and a dummy terminal portion 127 is formed with the insulating film 128 as illustrated in FIGS. 11 and 12. Note that, in FIG. 12, a range where the insulating film 128 is formed is illustrated with a hatch. The insulating film 128 has a band shape that extends over an almost overall length of a region where a flexible substrate 113 is mounted in the X-axis direction. Thus, the insulating film 128 is disposed so as to fill the insulating space 126 over an almost entire region, and disposed in a state of being interposed between all terminal portions 124 and all dummy terminal portions 127 that are disposed in the region where the flexible substrate 113 is mounted. Thereby, as compared to a case where the insulating film 128 is not formed as in Embodiment 1 described above, an insulating property of the terminal portion 124 against the dummy terminal portion 127 is further improved, so that more excellent resistance against the ESD of the source line 11J (refer to FIG. 3) is obtained.

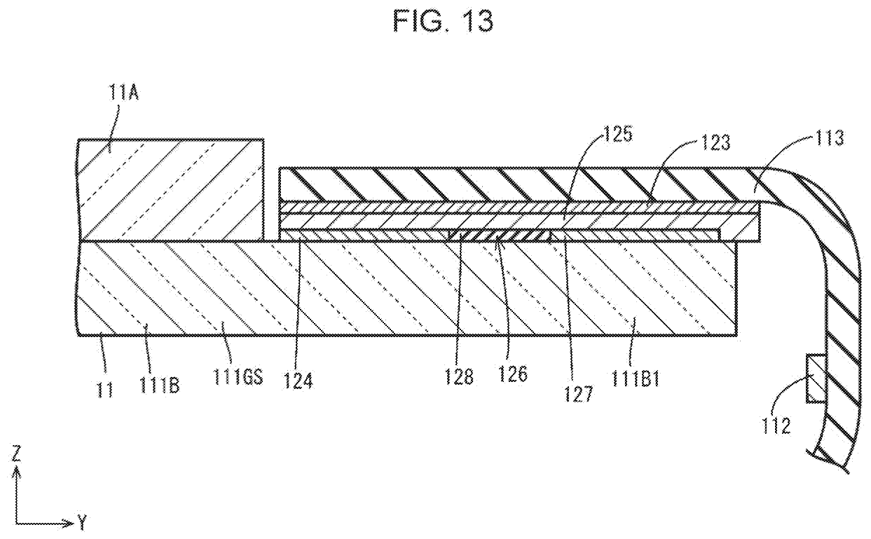

As illustrated in FIG. 11, the insulating film 128 has substantially the same thickness as those of the terminal portion 124 and the dummy terminal portion 127. Thus, surfaces of the insulating film 128, the terminal portion 124, and the dummy terminal portion 127 are almost flush with each other and are almost the same in a height from a plate surface of a glass substrate 111GS. According to such a configuration, when the flexible substrate 113 is mounted on the array substrate 111B, pressure applied to an anisotropic conductive film 125 interposed between the insulating film 128, the terminal portion 124, and the dummy terminal portion 127, and a terminal portion 123 of the flexible substrate 113 is made uniform over an almost entire region as illustrated in FIG. 13. Thereby, further improvement of bonding intensity is achieved and connection reliability between the terminal portion 124 and the terminal portion 123 of the flexible substrate 113 becomes much higher. Moreover, the insulating film 128 is preferably constituted by any of the gate insulating film 15, the first interlayer insulating film 18, the planarizing film 19, and the second interlayer insulating film 21 (refer to FIG. 4) that are provided in the array substrate 111B. The insulating film 128 is more preferably constituted by the planarizing film 19 of the respective insulating films 15, 18, 19, and 21 described above. The planarizing film 19 has a greatest film thickness among the films provided in the array substrate 111B, so that a thickness of a part forming the insulating film 128 is able to be easily adjusted.

As described above, the array substrate 111B according to the present embodiment includes the insulating film 128 that is disposed in the insulting space 126 provided in the glass substrate 111GS. Thereby, the insulating film 128 is interposed between the terminal portion 124 and the dummy terminal portion 127. As a result, as compared to a case where the insulating film 128 is not formed, an insulating property of the terminal portion 124 with respect to the dummy terminal portion 127 is improved, so that resistance against the ESD of the source line 11J becomes excellent.

Moreover, in the array substrate 111B according to the present embodiment, thicknesses of the terminal portion 124, the dummy terminal portion 127, and the insulating film 128 are substantially the same. Thereby, the terminal portion 124, the dummy terminal portion 127, and the insulating film 128 are equal in a height from a plate surface of the glass substrate 111GS. Accordingly, when the flexible substrate 113 is connected by using the anisotropic conductive film 125 as described above, pressure applied to the anisotropic conductive film 125 is made uniform. As a result, bonding intensity and connection reliability after pressure bonding become excellent.

### Embodiment 3

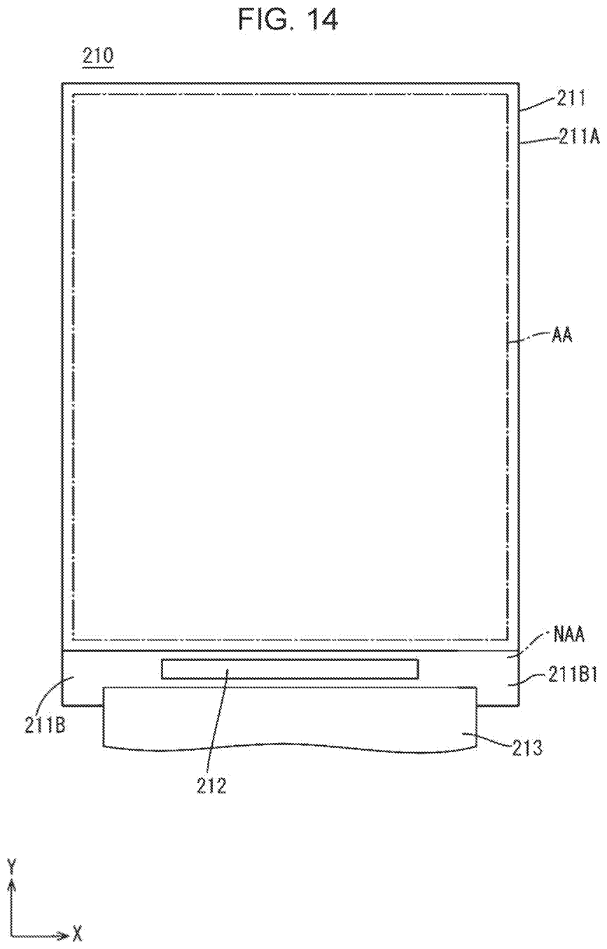

Embodiment 3 of the invention will be described with reference to FIGS. 14 to 16. In Embodiment 3, an array substrate 211B includes a driver IC 212. Note that, one having a similar configuration to that of Embodiment 1 described above will be given the same reference sign and redundant description for a structure, an action, and an effect thereof will be omitted.

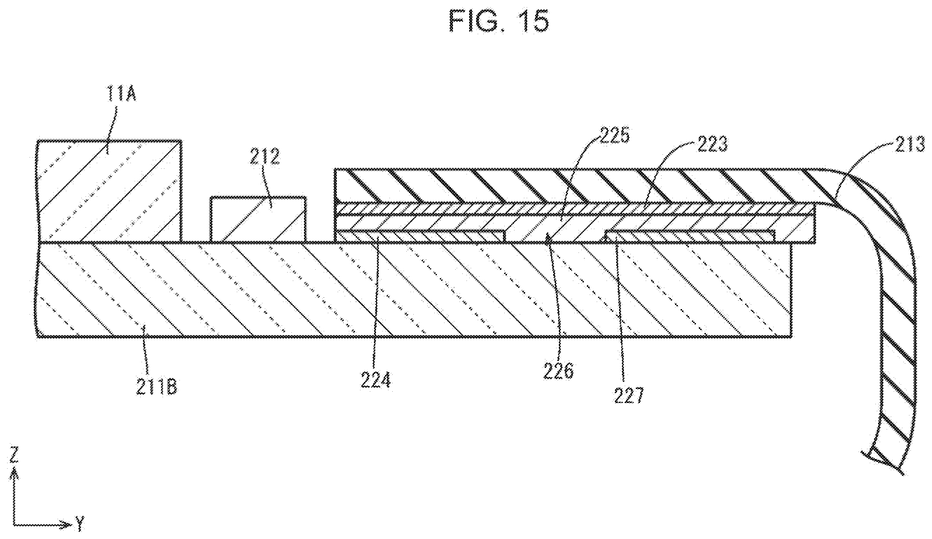

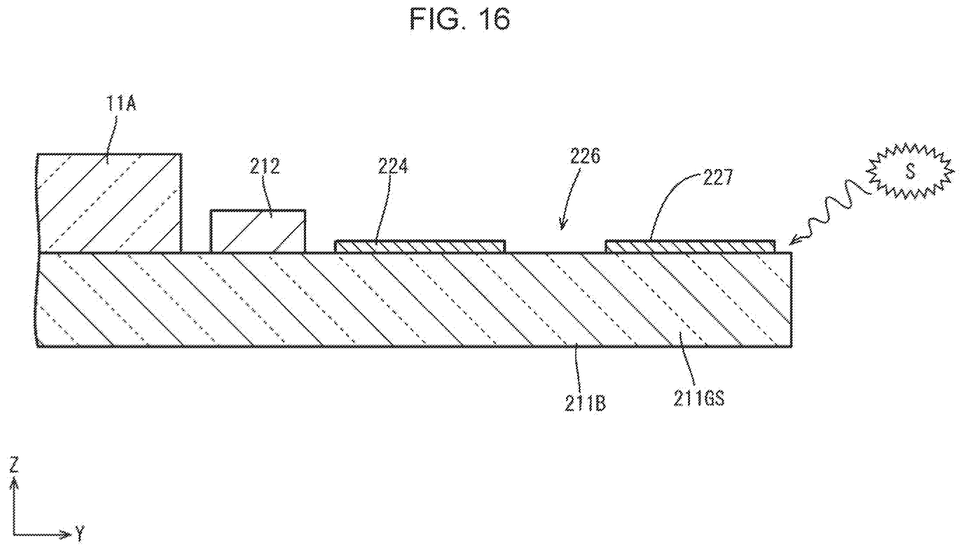

The driver IC 212 according to the present embodiment is COG mounted on a CF substrate non-overlapping portion 211B1 in the array substrate 211B as illustrated in FIGS. 14 and 15. The driver IC 212 is provided so as to be positioned between a region where a terminal portion 224 is disposed and a flexible substrate 213 is mounted and the display region AA where the source line 11J (refer to FIG. 3) is disposed, in the CF substrate non-overlapping portion 211B1. A signal input from the flexible substrate 213 to the terminal portion 224 is supplied to the driver IC 212. The driver IC 212 processes the signal supplied from the terminal portion 224 and thereby generates an output signal. The output signal output from the driver IC 212 is supplied to the source line 11J in the display region AA via a connection line. That is, the driver IC 212, the terminal portion 224, and the source line 11J are electrically connected to each other. Here, when it is assumed that the surge caused by the ESD is input to the terminal portion 224, the surge is input to the driver IC 212 from the terminal portion 224, so that the driver IC 212 may undergo electrostatic breakdown. In this regard, since a dummy terminal portion 227 is provided on an edge side of a glass substrate 211GS relative to the terminal portion 224 via an insulating space 226 as illustrated in FIG. 16, the surge caused by the ESD is difficult to be input to the terminal portion 224 and not only the source line 11J connected to the terminal portion 224 but also the driver IC 212 is able to be protected.

As described above, the array substrate 211B according to the present embodiment includes the driver IC (electronic component) 212 that is provided so as to be positioned between the terminal portion 224 and the source line 11J in the glass substrate (substrate portion) 211GS and that is electrically connected to the terminal portion 224 and the source line 11J. Thereby, the signal input to the terminal portion 224 is able to be supplied to the source line 11J after being processed by the driver IC 212. According to such a configuration, when it is assumed that the surge caused by the ESD is input to the terminal portion 224, not only the source line 11J but also the driver IC 212 may also undergo electrostatic breakdown. In this regard, since the dummy terminal portion 227 is provided in the glass substrate 211GS, the surge caused by the ESD is difficult to be input to the terminal portion 224 and not only the source line 11J connected to the terminal portion 224 but also the driver IC 212 is able to be protected.

### Embodiment 4

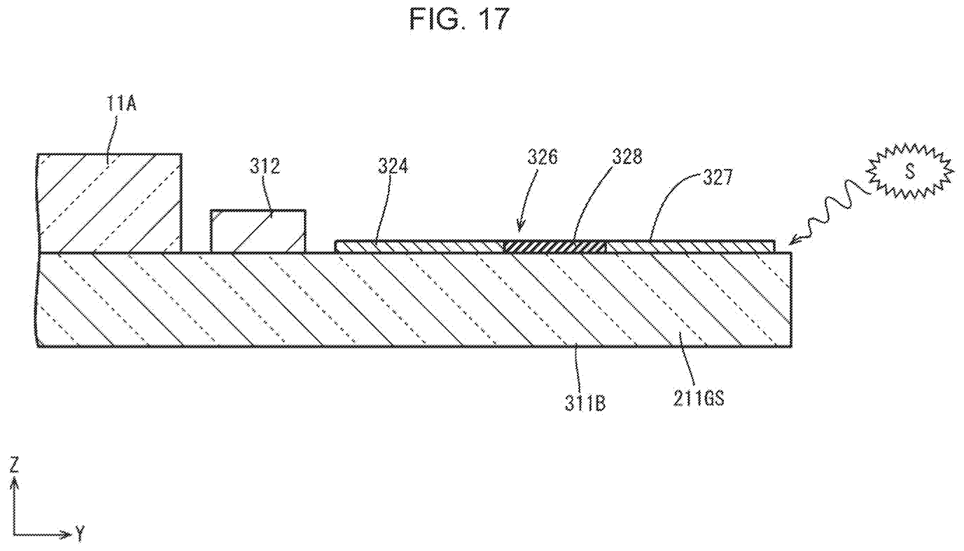

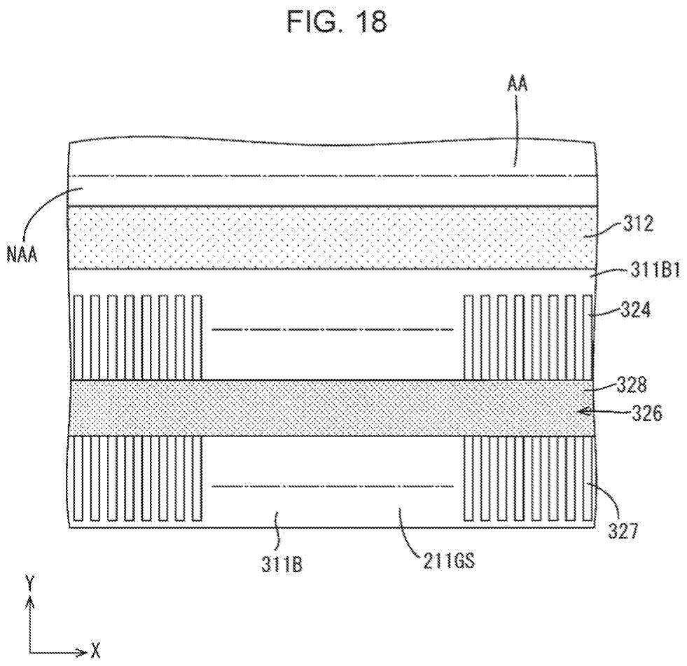

Embodiment 4 of the invention will be described with reference to FIGS. 17 and 18. In Embodiment 4, in addition to the configuration of Embodiment 3 described above, an array substrate 311B includes an insulating film 328 similar to that of Embodiment 2 described above. Note that, one having a similar configuration to that of Embodiment 3 described above will be given the same reference sign and redundant description for a structure, an action, and an effect thereof will be omitted.

In the array substrate 311B according to the present embodiment, the insulating film 328 is formed in an insulating space 326 disposed between a terminal portion 324 and a dummy terminal portion 327 as illustrated in FIGS. 17 and 18. A specific configuration of the insulating film 328 is as described in Embodiment 2 described above. When such an insulating film 328 is provided in the insulating space 326, the surge caused by the ESD is difficult to be input to the terminal portion 324. Thus, resistance against the ESD in a driver IC 312 connected to the terminal portion 324 is further improved. Note that, a range where the insulating film 328 is formed and a range where the driver IC 312 is formed are illustrated with different hatches in FIG. 18.

### Embodiment 5

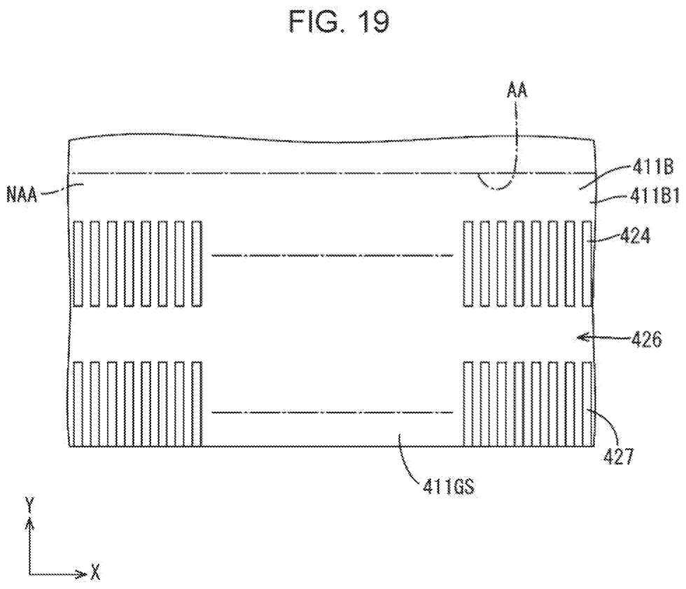

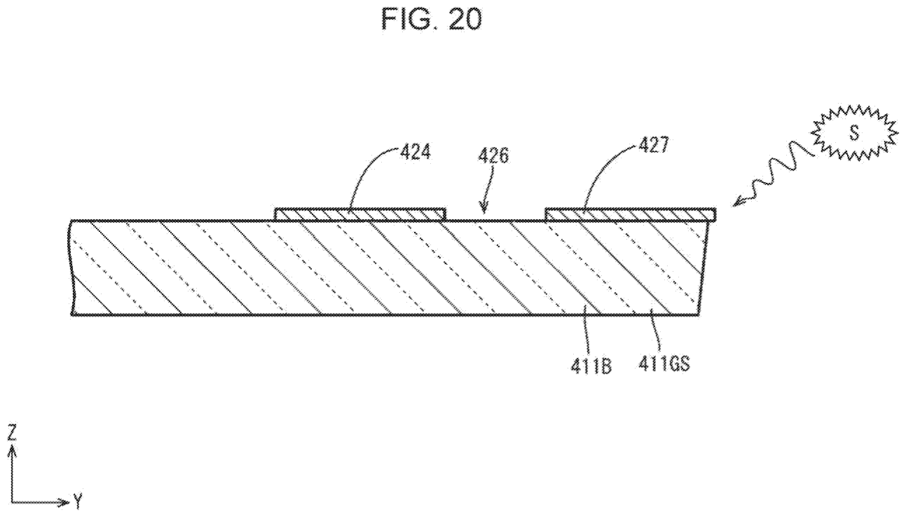

Embodiment 5 of the invention will be described with reference to FIGS. 19 and 20. In Embodiment 5, a dummy terminal portion 427 and a glass substrate 411GS have a configuration changed from the configuration of Embodiment 1 described above. Note that, one having a similar configuration to that of each of the embodiments described above will be given the same reference sign and redundant description for a structure, an action, and an effect thereof will be omitted.

An end of the dummy terminal portion 427 according to the present embodiment, which is closer to the edge of the glass substrate 411GS, is disposed so as to be flush with the edge of the glass substrate 411GS as illustrated in FIG. 19, or is disposed so as to slightly protrude from the edge of the glass substrate 411GS as illustrated in FIG. 20. Thereby, the dummy terminal portion 427 is disposed on the edge of the glass substrate 411GS and arrangement of an interval between the edge of the glass substrate 411GS and the dummy terminal portion 427 in the Y-axis direction is avoided. Thus, as compared to the arrangement in which the dummy terminal portion 27 is disposed so as to be retracted to the terminal portion 24 side relative to the edge of the glass substrate 11GS and an interval in the Y-axis direction is provided between the edge of the glass substrate 11GS and the dummy terminal portion 27 as described in Embodiment 1 described above, picture-frame narrowing of an array substrate 411B is able to be achieved.

As described above, according to the present embodiment, the dummy terminal portion 427 is disposed so that the end closer to the edge of the glass substrate 411GS protrudes from the edge of the glass substrate 411GS. Thereby, since the dummy terminal portion 427 is disposed on the edge of the glass substrate 411GS, as compared to a case where it is assumed that the dummy terminal portion is disposed so as to be retracted to the terminal portion side relative to the edge of the glass substrate, picture-frame narrowing is able to be achieved. Note that, when the dummy terminal portion 427 is disposed on the edge of the glass substrate 411GS, the surge caused by the ESD is more easily input to the dummy terminal portion 427, but a terminal portion 424 is separated from the dummy terminal portion 427 by an insulating space 426, and therefore, even when it is assumed that the surge caused by the ESD is input to the dummy terminal portion 427, reaching of the surge to the terminal portion 424 is avoided and the terminal portion 424 and the source line or the like connected to the terminal portion 424 are able to be protected against the surge.

### OTHER EMBODIMENTS

The invention is not limited to the embodiments described with reference to the aforementioned description and drawings. For example, the following embodiments are also included in a technical scope of the invention.

(1) Though each of the embodiments described above indicates the array substrate including the TFT on the glass substrate, an array substrate including a switching element other than the TFT may be used.

(2) Though each of the embodiments described above indicates a case of the array substrate used for the liquid crystal panel, a circuit substrate used for a display panel other than the liquid crystal panel, for example, an organic EL display (OLED) may be used.

(3) Though each of the embodiments described above indicates the array substrate used for the liquid crystal panel, the invention is applicable also to a circuit substrate used for other than a display panel including the liquid crystal panel as long as including a circuit or an electronic component to be protected against a surge caused by ESD.

(4) Though each of the embodiments described above indicates a configuration in which the flexible substrate is connected to the array substrate, a configuration in which a rigid substrate instead of the flexible substrate is connected may be provided.

(5) Though each of the embodiments described above indicates a configuration in which the array substrate and the flexible substrate are connected by using the anisotropic conductive film, a configuration in which the connection is performed not by the anisotropic conductive film but by, for example, isotropic conductive adhesive may be provided.

(6) Though each of the embodiments described above indicates a configuration in which the width dimensions and the array pitches of the terminal portion and the dummy terminal portion are the same, a configuration in which one or both of the width dimensions and the array pitches of both of the terminal portions are different may be provided.

(7) Though each of the embodiments described above indicates a configuration in a case where the thicknesses of the terminal portion and the dummy terminal portion are substantially the same, a configuration in which the thicknesses of the portions are different may be provided. Similarly, though Embodiments 2 and 4 described above indicate a configuration in a case where the thicknesses of the terminal portion, the dummy terminal portion, and the insulating film are substantially the same, a configuration in which the thicknesses of the portions are different may be provided.

(8) Though each of the embodiments described above indicates a configuration in which one terminal portion and one dummy terminal portion are arrayed so as to be paired, when a configuration in which the width dimensions and the array pitches are differentiated as in (6) described above is adopted, an array in which one dummy terminal portion is arranged on an edge side of the glass substrate relative to a plurality of terminals may be provided.

(9) Though each of the embodiments described above indicates a case of an array in which the side edges of the terminal portion and the dummy terminal portion that are the same in the width dimension and the array pitch are aligned so as to be in line with each other, an array in which the side edges of the terminal portion and the dummy terminal portion that are the same in the width dimension and the array pitch are offset may be provided. Moreover, the terminal portion and the dummy terminal portion may be arrayed in zig zag, while the side edges of the terminal portion and the dummy terminal portion that are the same in the width dimension and the array pitch are aligned so as to be in line with each other.

(10) Though each of the embodiments described above exemplifies a configuration in which both of planar shapes of the terminal portion and the dummy terminal portion are rectangular shapes, the planar shapes of the terminals are not limited to the rectangular shapes, and may be, for example, elliptical shapes, circular shapes, or polygonal shapes other than the rectangular shapes.

(11) Though Embodiment 5 described above indicates a case where a part of the configuration is changed on the basis of the configuration of Embodiment 1, the part of the configuration may be changed on the basis of not the configuration of Embodiment 1 but the configuration of any of Embodiments 1 to 4.

(12) Though each of the embodiments described above indicates a case where the terminal portion and the dummy terminal portion are disposed in respective short-side parts of the array substrate, a configuration in which the terminal portion and the dummy terminal portion are disposed in respective long-side parts of the array substrate may be provided.

(13) Though Embodiment 2 and Embodiment 4 described above indicate a case where the insulating film provided in the insulating space is formed by using any of the insulating films originally provided in the array substrate, installation in which an insulating film that is prepared separately from the respective insulating films originally provided in the array substrate is attached to the insulating space afterward is also possible.

(14) Though Embodiment 5 described above indicates a configuration in which the end of the dummy terminal portion, which is closer to the edge of the glass substrate, is disposed so as to protrude from the edge of the glass substrate, the end of the dummy terminal portion, which is closer to the edge of the glass substrate, may be disposed so as to be flush with the edge of the glass substrate.

(15) Though each of the embodiments described above exemplifies the liquid crystal panel whose operation mode is the FFS mode, a liquid crystal panel whose operation mode is another operation mode such as an in-plane switching (IPS) mode or a vertical alignment (VA) mode may be provided.

What is claimed is:

1. A circuit substrate comprising:
a substrate portion;
a circuit portion that is provided on the substrate portion;
a terminal portion that is provided on the substrate portion and connected to the circuit portion; and
a dummy terminal portion that is disposed at a position closer to an edge than the terminal portion is on the substrate portion so as to be spaced from the terminal portion with an insulating space between the terminal portion and the dummy terminal portion.

2. The circuit substrate according to claim 1, wherein thicknesses of the terminal portion and the dummy terminal portion are substantially identical with each other.

3. The circuit substrate according to claim 1, wherein a plurality of terminal portions, each of which is the terminal portion that is provided on the substrate portion and connected to the circuit portion, and a plurality of dummy terminal portions, each of which is the dummy terminal portion that is disposed at the position closer to the edge than the terminal portion is on the substrate portion so as to be spaced from the terminal portion with the insulating space between the terminal portion and the dummy terminal portion, are arranged each with an interval at positions with the insulating space between the plurality of terminal portions and the plurality of dummy terminal portions, and are equal in a width dimension and an array pitch.

4. The circuit substrate according to claim 3, wherein the terminal portion and the dummy terminal portion are disposed so that a side edge of the terminal portion and a side edge of the dummy terminal portion along an arrangement direction are aligned so as to be in line with each other.

5. The circuit substrate according to claim 1, further comprising an insulating film that is provided on the substrate portion and disposed in the insulating space.

6. The circuit substrate according to claim 5, wherein thicknesses of the terminal portion, the dummy terminal portion, and the insulating film are substantially identical with each other.

7. The circuit substrate according to claim 1, further comprising an electronic component that is provided so as to be positioned between the terminal portion and the circuit portion on the substrate portion and electrically connected to the terminal portion and the circuit portion.

8. The circuit substrate according to claim 1, wherein the substrate portion is sectioned into a display region in which at least the circuit portion is disposed and an image is displayed and a non-display region which is disposed outside the display region and in which at least the terminal portion, the insulating space, and the dummy terminal portion are disposed.

9. The circuit substrate according to claim 1, wherein an end of the dummy terminal portion, which is closer to the edge of the substrate portion, is disposed so as to be flush with the edge of the substrate portion or so as to protrude from the edge of the substrate portion.

10. A display apparatus comprising:
the circuit substrate according to claim 1; and
a counter substrate that is bonded to the circuit substrate in an opposed manner.
